(19) United States
(12) Patent Application Publication
(10) Pub. No.: US 2026/0372090 A1
(43) Pub. Date: Nov. 19, 2026

(54) INTERPOSER WITH INTEGRATED MICROCHANNEL COOLERS

(71) Applicant: INTERNATIONAL BUSINESS MACHINES CORPORATION, Armonk, NY (US)

(72) Inventors: John Knickerbocker, Monroe, NY (US); Mukta Ghate Farooq, Hopewell Junction, NY (US); Todd Edward Takken, Brewster, NY (US); John W. Golz, Hopewell Junction, NY (US); Hemanth Jagannathan, Niskayuna, NY (US); Keiji Matsumoto, Yokohama-shi (JP)

(21) Appl. No.: 19/208,969

(22) Filed: May 15, 2025

(51) Int. Cl. H10W 40/47; H10W 70/63; H10W 70/65; H10W 90/00

(52) U.S. Cl. CPC H10W 40/47; H10W 70/635; H10W 70/65; H10W 90/00

(57) ABSTRACT

An interposer includes a microchannel cooler layer including a microchannel cooler. The microchannel cooler has mandrels connected between an inlet and an outlet. The mandrels are thermally conductive to permit heat transfer from the plurality of mandrels to the inlet and the outlet. A redistribution layer on the microchannel cooler layer and having openings fluidly connected to the inlet and the outlet to permit fluid flow between the inlet and the outlet.

### BACKGROUND

The present invention generally relates to semiconductor package devices and processing methods, and more particularly to interposers with active heat control.

An intermediate substrate can be employed between printed circuit boards and chips in semiconductor device packaging. The intermediate substrate can be employed between printed circuit boards and chips. The intermediate substrate can include an interposer that acts as an interface between structures in a three-dimensional package structure. Interposers enable high-density integration, signal routing, and mechanical support for advanced semiconductor packages.

While conventional organic-based interposers provide passive heat dissipation through embedded metal structures such as copper traces and vias, they lack active or enhanced thermal management capabilities. This passive approach to heat dissipation is often insufficient for modern high-performance semiconductor devices, which generate increasing amounts of heat due to higher power densities, smaller form factors, and faster processing speeds. Without effective heat removal, elevated operating temperatures can result in thermal throttling, reduced performance, and long-term reliability concerns, including accelerated material degradation and failure of solder joints or interconnects.

### SUMMARY

In accordance with an embodiment of the present invention, an interposer includes a microchannel cooler layer including a microchannel cooler. The microchannel cooler has mandrels connected between an inlet and an outlet. The mandrels are thermally conductive to permit heat transfer from the plurality of mandrels to the inlet and the outlet. A redistribution layer on the microchannel cooler layer and having openings fluidly connected to the inlet and the outlet to permit fluid flow between the inlet and the outlet.

In accordance with another embodiment of the present invention, a device includes a substrate, and an interposer connected to the substrate. The interposer includes at least one microchannel cooler. At least one semiconductor chip is connected to the interposer wherein the at least one microchannel cooler is configured to provide active cooling to the at least one semiconductor chip.

In accordance with another embodiment of the present invention, a device includes a substrate, and a first interposer connected to the substrate. The first interposer has at least one microchannel cooler. At least one semiconductor chip is connected to the first interposer. A second interposer includes at least one microchannel cooler. An external plumbing structure is fluidly connected to the microchannel coolers of the first and second interposers.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures, wherein:

FIG. 1 shows a cross-sectional view of a semiconductor package having an interposer with microchannel coolers, in accordance with an embodiment of the present invention;

FIG. 2 shows a cross-sectional view of a semiconductor package having an interposer with bridge chips disposed therein separating microchannel coolers, in accordance with an embodiment of the present invention;

FIG. 3 shows a cross-sectional view of a semiconductor package having an interposer with bridge chips and a voltage regulation module disposed adjacent to microchannel coolers, in accordance with an embodiment of the present invention;

FIG. 4 shows a cross-sectional view of a semiconductor package having two interposers with microchannel coolers to actively reduce heat in a plurality of adjacent chips, in accordance with an embodiment of the present invention;

FIG. 5 shows a cross-sectional view of a semiconductor package having two interposers with microchannel coolers connected by external plumbing to actively reduce heat in a plurality of adjacent chips, in accordance with an embodiment of the present invention;

FIG. 6 is a top view showing microchannel cooler structures on a temporary carrier, in accordance with an embodiment of the present invention;

FIG. 7 is a top view showing the microchannel cooler structures covered by molding material, in accordance with an embodiment of the present invention;

FIG. 8 is a top view showing the microchannel cooler structures exposed after some of the molding material is removed, in accordance with an embodiment of the present invention;

FIG. 9 is a top view showing the microchannel cooler structures after forming a redistribution layer thereon and showing openings formed through the redistribution layer to expose material in the microchannel cooler structures, in accordance with an embodiment of the present invention;

FIG. 10 is a top view showing dice cuts for dicing the temporary carrier to form interposers with microchannel coolers, in accordance with an embodiment of the present invention;

FIG. 11 is a top view showing an interposer with microchannel coolers opened up by removing a temporary fill, in accordance with an embodiment of the present invention;

FIG. 12 is a top view showing a radial burst pattern for mandrels and channels of a microchannel cooler, in accordance with an embodiment of the present invention;

FIG. 13 is a top view showing lateral connections between microchannel coolers using mold material to form pipes therebetween, in accordance with an embodiment of the present invention;

FIG. 14 shows a cross-sectional view of a semiconductor package having an interposer with microchannel coolers connected to a manifold or plumbing, in accordance with an embodiment of the present invention;

FIG. 15 shows a cross-sectional view of a semiconductor package having a first interposer with microchannel coolers formed on a substrate, in accordance with an embodiment of the present invention;

FIG. 16 shows a cross-sectional view of the semiconductor package having chips connected on the first interposer with microchannel coolers and molding material formed about the chips, in accordance with an embodiment of the present invention;

FIG. 17 shows a cross-sectional view of the semiconductor package having the molding material opened up to expose the first interposer, in accordance with an embodiment of the present invention;

FIG. 18 shows a cross-sectional view of the semiconductor package having a second interposer with microchannel coolers connected to one of the chips, in accordance with an embodiment of the present invention;

FIG. 19 shows a cross-sectional view of the semiconductor package having a film-type underfill opened up on the second interposer to form openings that expose the first interposer, in accordance with an embodiment of the present invention;

FIG. 20 shows a cross-sectional view of the semiconductor package having the openings that expose the first interposer filled with a temporary fill, in accordance with an embodiment of the present invention;

FIG. 21 shows a cross-sectional view of the semiconductor package having the second interposer prepared for attaching additional chips, in accordance with an embodiment of the present invention;

FIG. 22 shows a cross-sectional view of the semiconductor package having additional chips connected to the second interposers, filled with a molding material and the molding material is opened up to expose the temporary fill, in accordance with an embodiment of the present invention;

FIG. 23 shows a cross-sectional view of the semiconductor package having temporary fill added in the openings and a heat spreader assembled on the semiconductor package, in accordance with an embodiment of the present invention; and

FIG. 24 is a schematic block diagram showing a plumbing control loop for controlling flow in a microchannel cooler, in accordance with an embodiment of the present invention.

### DETAILED DESCRIPTION

In accordance with embodiments of the present invention, devices and methods are described which include an interposer or interposer substrate with active cooling capabilities. Interposers are provided having integrated microchannel coolers that employ molding compounds, which can include organic materials to provide channels and manifolding for fluid inlet and outlet. Since the interposers include moving fluids, the interposers provide active cooling capabilities to reduce heat loads of individual chips or stacks of chips. The interposers can employ at least one electrical conduit or electrical via repurposed for fluid channels. The interposers can include integrated microchannel coolers that can be positioned to work in two-dimensional (2D) configurations (e.g., 2.xD case) as well as three-dimensional (3D) configurations. 3D configurations can include interposers between one or more chips or substrates in a stack. For the 3D case, in an embodiment, at least one interposer can be located above a chip and at least one interposer can be located below a chip. Other configurations are also contemplated. A chiplet, chip or semiconductor chip refers to a heat generating integrated circuit (IC) including but not limited to an electronic device or photonics device. The IC can include one or more of transistors, capacitors, resistors, and other electronic and/or optical components that are interconnected to perform specific functions.

In an embodiment, the interposer includes a microchannel cooler layer that include one or more microchannel coolers. In other embodiments the interposer can include multiple microchannel cooler layers in the same interposer.

Each microchannel in an interposer can be connected with manifolded structures for coolant inlets and outlets. The manifold structures can be disposed on the interposers or externally to the interposer. In an embodiment, an externally disposed manifold structure can fluidly connect multiple interposers in a device stack. Fluidly connect refers to enabling fluid to flow through a connection or between components that are fluidly connected.

Each interposer can include portions or segments having microchannel coolers. The microchannel coolers in the portions or segments can be sized and configured in accordance with corresponding chips or heat loads to which the portions or segments will be cooling. In some embodiments, components, such as bridge chips, voltage regulator modules (VRMs) or other devices can also be included within an interposer.

In an embodiment, an interposer and/or its portions or segments can include channels or microchannels that span between a fluid inlet on one side and a fluid outlet on an opposite side. The microchannels can be open to permit fluid flow or solid to permit heat to flow. The microchannels can include walls made of Si, metal, ceramic, graphite, diamond or other suitable materials.

The interposer or portion thereof can include at least one optical link or electrical line in a vertical and/or a horizontal direction. The optical link or electrical line can be employed as a mandrel for a microchannel. Different-sized microchannels can be located in horizontal and/or in vertical directions. The microchannels can include different shapes and patterns, for example, the microchannels can be straight and/or radially arranged. In an embodiment, an interposer can be located between a chip and a substrate, between chips, above a chip, below a chip or above and below a chip. An interposer can be applied to a wafer scale structure or a die scale structure and/or applied to multiple chips (dies).

In some embodiments, a pre-fabricated manifold can be combined with a molded interposer package or microchannel cooler. The pre-fabricated manifold can permit a coarse interface between the molded interposer package and external cooling structures that bring coolant into and out of the molded interposer package or packages or to and from a heat pipe. A lid (e.g., a heat spreader) and/or manifolded coolant channels can be molded or otherwise integrated into external cooling structures. A manifold can have multiple inlet and outlet apertures to optimize flow and pressure drop. A microchannel cooler in the interposer can include a single-phase flow (e.g., gas or liquid) or a two-phase flow (e.g., gas and liquid). Fluid of the microchannel cooler can include a dielectric material. In a single-phase microchannel cooler, sizes of microchannels can be uniform. Heights of vias (through mold vias) and/or heights of interconnects for fluid channels can be varied for expansion purposes in two-phase flows. Two-phase flow can be generated by controlling cooling structure sizes, shape height, length of channels and input / output manifolds, and/or electrical and optical interconnection structures that are made within, through or adjacent to microchannel coolers. Chips or chiplets can be angled (tilted) for expansion purposes in two-phase flow devices.

Thermal insulators can be located between memory devices (e.g., SRAM, DRAM, analog memory) and systems-on-a-chip (SOC) within a stack. Fluid temperature of each microchannel cooler can be controlled depending on the target temperature of each chip, such as, e.g., in multi-chip packages or in optics packages, photonics integrated chips, electronic integrated chips or combinations thereof. A micro-electro-mechanical system (MEMS) technology flow meter that combines miniature mechanical and electrical components can be used in a feedback loop of fluid in microchannel coolers to assist in controlling flow.

In accordance with an embodiment of the present invention, an interposer includes a microchannel cooler layer including a microchannel cooler. The microchannel cooler has mandrels connected between an inlet and an outlet. The mandrels are thermally conductive to permit heat transfer from the plurality of mandrels to the inlet and the outlet. A redistribution layer on the microchannel cooler layer and having openings fluidly connected to the inlet and the outlet to permit fluid flow between the inlet and the outlet. The microchannel cooler provides active cooling to adjacent structures of a semiconductor package or to chip on or in the interposer.

In other embodiments, the mandrels can form channels to permit fluid flow between the inlet and the outlet. The mandrels can include electrical vias and/or optical waveguides. The electrical and/or optical vias can be active and carry signals. The mandrels can be configured in a radial burst pattern. This can concentrate heat transfer in particular regions. The interposer can include a plurality of microchannel coolers where each microchannel cooler corresponds to a specific heat load generated by adjacent structures (e.g., chips or components). A semiconductor chip can be disposed within the interposer and can be cooled using the microchannel cooler(s). The interposer can include two or more microchannel coolers, and a semiconductor chip can be disposed between microchannel coolers.

In accordance with another embodiment of the present invention, a device includes a substrate, and an interposer connected to the substrate. The interposer includes at least one microchannel cooler. At least one semiconductor chip is connected to the interposer wherein the at least one microchannel cooler is configured to provide active cooling to the at least one semiconductor chip. The microchannel cooler provides active cooling to the semiconductor package.

In other embodiments, the at least one microchannel cooler can include a plurality of microchannels configured for fluid flow. The plurality of microchannels can be formed between mandrels within the interposer. The mandrels can include electrical vias and/or optical waveguides. The electrical and/or optical vias can be active and carry signals. A manifold structure can be fluidly connected to the at least one microchannel cooler. The manifold structure can be external to the interposer. A plumbing control loop can have a micro-electro-mechanical system flow meter to control a flow through the at least one microchannel cooler. Another chip can be disposed within the interposer between adjacent microchannel coolers.

In accordance with another embodiment of the present invention, a device includes a substrate, and a first interposer connected to the substrate. The first interposer has at least one microchannel cooler (first microchannel cooler). At least one semiconductor chip is connected to the first interposer. A second interposer includes at least one microchannel cooler (second microchannel cooler). An external plumbing structure is fluidly connected to the microchannel coolers of the first and second interposers. The microchannel cooler provides active cooling to the semiconductor package.

In other embodiments, the microchannel coolers of the first and second interposers can be configured to provide active cooling to the at least one semiconductor chip wherein the external plumbing structure includes fluid inlet and outlet connections to provide coolant flow through the microchannel coolers. The microchannel coolers can include a plurality of microchannels formed between mandrels within the interposers, wherein the mandrels include electrical vias that provide electrical connections and optical waveguides that provide optical connections. The electrical and/or optical vias can be active and carry signals. A second semiconductor chip can be connected to the second interposer. The external plumbing structure can include a manifold having inlet and outlet portions fluidly connected with the microchannel coolers of the first and second interposers.

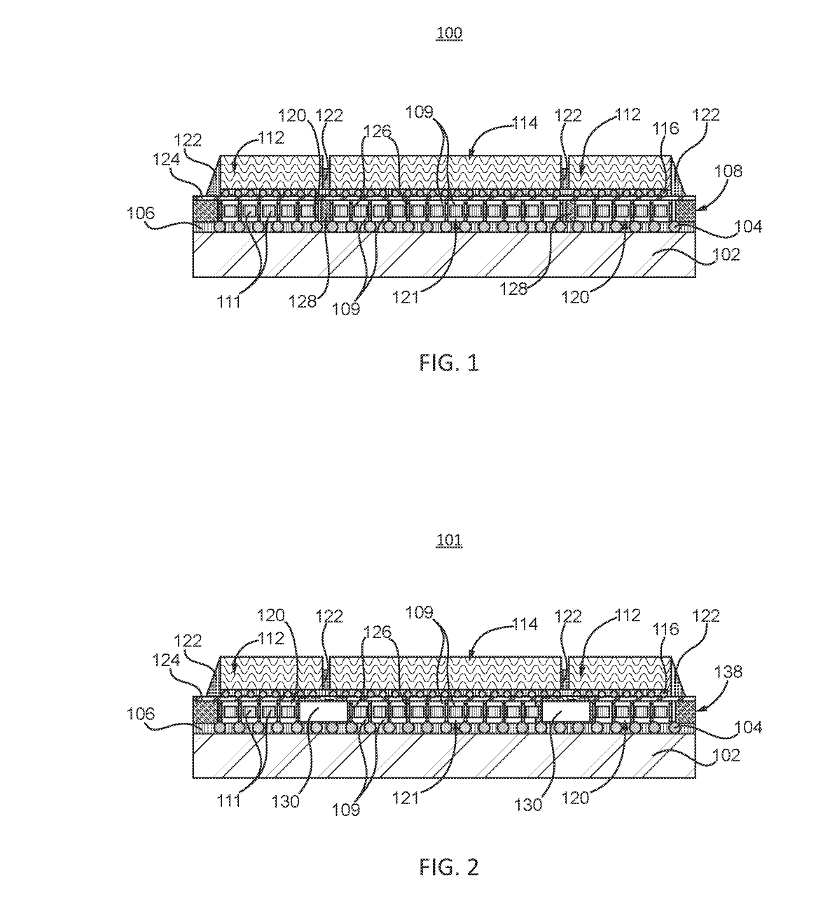

Referring now to the drawings in which, like numerals represent the same or similar elements and initially to FIG. 1, a cross-sectional view of a semiconductor package 100 is shown in accordance with embodiments of the present invention. The semiconductor package 100 includes a substrate 102, which can include a printed circuit board (PCB). The substrate 102 can be connected to an interposer 108. The substrate 102 can be electrically connected to the interposer 108 by solder balls 104 in a ball grid array, which are encased in an underfill material 106. The underfill material 106 can include, e.g., an epoxy. The interposer 108 is further connected to other components opposite to the substrate 102. The other components can include, e.g., high bandwidth memory chips (HBMs 112), system-on-a-chip (SOC 114), other memory devices or other components, etc. The HBMs 112 and SOC 114 electrically connect to the interposer 108 using solder balls 116 in a ball grid array, which are also encased in underfill 124 or mold material. The underfill 124 or mold material can include, e.g., an epoxy. An underfill 122 or mold material can be employed to fill gaps and provide support to structures of the semiconductor package 100. The underfill 122 or mold material can include, e.g., an epoxy.

The interposer 108 includes microchannel coolers 120 and 121. The microchannel coolers 120 correspond with locations of the HBMs 112 and provide active cooling to the HBMs 112 and to the substrate 102. The microchannel cooler 121 corresponds with locations of the SOC 114 and provides active cooling to the SOC 114 and to the substrate 102. The microchannel coolers 120 and 121 are separated by barriers 128, which can be designed and sized to address the cooling needs of each component (e.g., HBMs 112, SOC 114, etc.). The barriers 128 can include thermally conductive material or thermally insulative materials depending on the goals of the heat transfer profile desired. The barriers 128 can prevent thermal cross-talk between adjacent components. Active cooling refers to cooling by fluid flow within or through portions of the components (e.g., within channels or plumbing) as opposed to passive cooling which just uses conduction.

The microchannel coolers 120 and 121 can include mandrels 126, which can include electrical conduits (e.g., electrical vias) or optical waveguides that can be employed to provide channel structures and heat conduction paths. The mandrels 126 can include active electrical or optical signal paths that traverse the interposer 108. The mandrels 126 can be part of the construction and design of the interposer 108 and configured and placed to form microchannel coolers 120, 121 in regions of higher heat loads. For example, the mandrels 126 can form channel sidewalls. The microchannel coolers 120, 121 can each be positioned to address a specific heat load from nearby or adjacent components.

The microchannel coolers 120 and 121 can include structures and plumbing that is installed during assembly of the semiconductor package 100. The microchannel coolers 120 and 121 can include discrete structures formed during the fabrication of the interposer 108 and can include plumbing connected to the microchannel coolers 120 and 121, which can be installed during assembly of the semiconductor package 100. In an embodiment, the microchannel coolers 120 and 121 of the interposer 108 include channels or microchannels 109 that can support fluid flow. The microchannels 109 can be formed on one side or opposite sides of a layer 111. The layer 111 can include a substrate that can include a semiconductor material or a dielectric material. The mandrels 126 can run through the layer 111 (e.g., through silicon) or be formed on one side thereof.

In another embodiment, the microchannel coolers 120 and 121 of the interposer 108 include solid materials that span across an area between an inlet and an outlet for fluid flow. In this embodiment, the mandrels 126 of the microchannel coolers 120 and 121 can be solid material that transfers heat to the inlet and outlet fluids that flow through manifolds across the interposer 108. The microchannel coolers 120 and 121 can include an inlet connected on first ends of the mandrels 126 and an outlet on second ends of the mandrels 126. In this embodiment, the mandrels 126 do not carry fluid but carry heat to the fluid in the inlet and outlet at the ends of the mandrels 126.

Referring to FIG. 2, a cross-sectional view of a semiconductor package 101 is shown in accordance with embodiments of the present invention. The semiconductor package 101 includes substrate 102. The substrate 102 can be connected to an interposer 138. The substrate 102 can be electrically connected to the interposer 138 by solder balls 104 encased in underfill material 106. The interposer 138 is further connected to other components opposite the substrate 102. The other components can include, e.g., HBMs 112, SOC 114, other memory devices or other components, etc. The HBMs 112, SOC 114 electrically connect to the interposer 138 using solder balls 116 encased in in underfill 124. The underfill 122 or mold material can be employed to fill gaps and provide support to the semiconductor packages described.

The interposer 138 includes microchannel coolers 120 and 121. The microchannel coolers 120 correspond with the HBMs 112 and provide active cooling to the HBMs 112 and to the substrate 102. The microchannel cooler 121 corresponds with the SOC 114 and provides active cooling to the SOC 114 and to the substrate 102. In this embodiment, the microchannel coolers 120 and 121 are separated by bridge chips 130 disposed within a plane of the interposer 138 and acting as thermal barriers between adjacent microchannel coolers 120 and 121. The bridge chips 130 can include electronic devices that optically or electrically interface between the substrate 102 and other chips or components of the semiconductor package 101. The bridge chips 130 can provide prevention of thermal cross-talk between adjacent components.

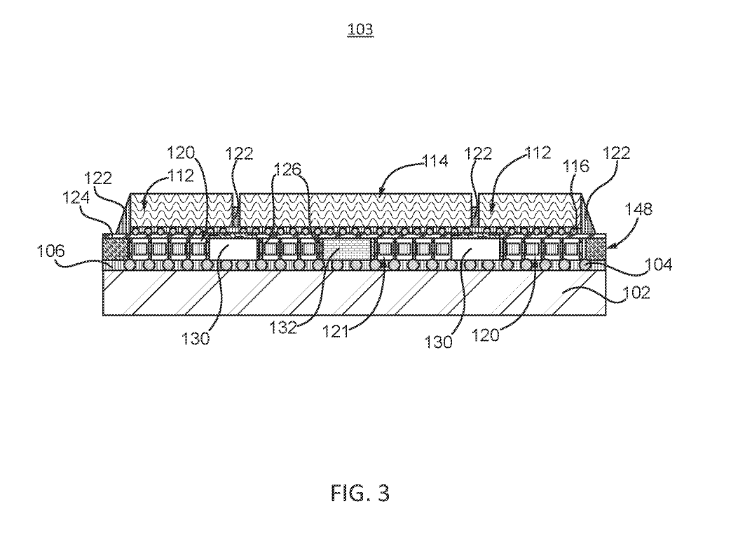

Referring to FIG. 3, a cross-sectional view of a semiconductor package 103 is shown in accordance with embodiments of the present invention. The semiconductor package 103 includes substrate 102. The substrate 102 can be connected to an interposer 148. The substrate 102 can be electrically connected to the interposer 148 by solder balls 104 encased in underfill material 106. The interposer 138 is further connected to other components opposite the substrate 102. The other components can include, e.g., HBMs 112, SOC 114, other memory devices or other components, etc. The HBMs 112, SOC 114 electrically connect to the interposer 138 using solder balls 116 encased in in underfill 124.

The interposer 138 includes microchannel coolers 120 and 121. The microchannel coolers 120 correspond with the HBMs 112 and provide active cooling to the HBMs 112 and to the substrate 102. The microchannel cooler 121 corresponds with the SOC 114 and provides active cooling to the SOC 114 and to the substrate 102. The microchannel coolers 120 and 121 are separated by bridge chips 130 disposed within a plane of the interposer 148 and acting as barriers between adjacent microchannel coolers 120 and 121. In addition, a voltage regulation module (VRM 132) or other chip or components can be disposed within microchannel cooler 121 within the interposer 148. The VRM 132 can interact with the SOC 114 and the substrate 102. Portions of the adjacent microchannel cooler 121 can be employed to reduce an operating temperature of the VRM 132 as well.

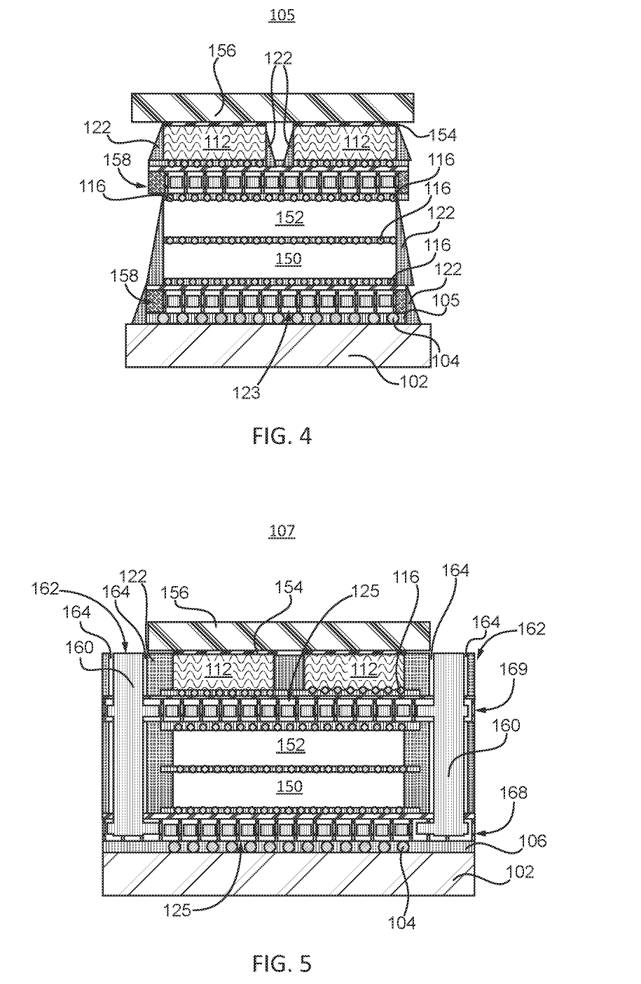

Referring to FIG. 4, a cross-sectional view of a semiconductor package 105 is shown in accordance with embodiments of the present invention. The semiconductor package 105 includes substrate 102. The substrate 102 can be connected to an interposer 158. The substrate 102 can be electrically connected to the interposer 158 by solder balls 104 encased in underfill material 106. The interposer 158 is further connected to other components opposite the substrate 102. The other components can include, e.g., memory chip 150, such as e.g., a static random-access memory (SRAM) or other memory devices or other components, etc. The memory chip 150 electrically connects to the interposer 158 using solder balls 116 encased in in underfill. The memory chip 150 electrically connects to a SOC 152 opposite the interposer 158 using solder balls 116 encased in underfill.

Interposers 158 include microchannel coolers 123. A microchannel cooler 123 corresponds with the memory chip 150 and provides active cooling to the memory chip 150 and to the substrate 102. A microchannel cooler 123 corresponds with the SOC 152 and provides active cooling to the SOC 152 and to HBMs 112, which are placed opposite the SOC 152. The HBMs 112 can have further thermal management using a heat spreader 156 or heat sink. The heat spreader 156 can be coupled to the HBMs 112 using a thermal interface material (TIM) 154.

The semiconductor package 105 of this embodiment includes two independent interposers 158. Each interposer 158 is assigned to actively cool a different component, e.g., memory chip 150 and SOC 152. It should be understood that any number of cooling interposers can be employed in a package stack, and that the package stack can include any number of different configurations. Each cooling interposer can be customized for the heat load that the cooling interposer is to address.

Referring to FIG. 5, a cross-sectional view of a semiconductor package 107 is shown in accordance with embodiments of the present invention. The semiconductor package 107 includes substrate 102. The substrate 102 can be connected to an interposer 168. The substrate 102 can be electrically connected to the interposer 168 by solder balls 104 encased in underfill material 106. The interposer 168 is further connected to other components opposite the substrate 102. The other components can include, e.g., memory chip 150, such as. e.g., a static random-access memory (SRAM) or other memory devices or other components, etc. The memory chip 150 electrically connects to the interposer 168 using solder balls 116 encased in underfill. The memory chip 150 electrically connects to a SOC 152 opposite the interposer 168 using solder balls 116 encased in underfill.

A microchannel cooler 125 corresponds with the memory chip 150 and provides active cooling to the memory chip 150 and to the substrate 102. A microchannel cooler 125 of an interposer 169 corresponds with the SOC 152 and provides active cooling to the SOC 152 and to HBMs 112, which are placed opposite the SOC 152. The HBMs 112 can have further thermal management using a heat spreader 156 or heat sink. The heat spreader 156 can be coupled to the HBMs 112 using a TIM 154.

The semiconductor package 107 of this embodiment includes two connected interposers 168, 169. The interposers 168, 169 are commonly connected to external plumbing 162. External plumbing 162 or manifold includes inlet and outlet portions 164, which fluidly communicate with microchannels of the microchannel coolers 125 of the interposers 168, 169. Each interposer 168, 169 is assigned to actively cool a different component, e.g., memory chip 150 and/or SOC 152. It should be understood that any number of cooling interposers can be employed in a package stack. Each cooling interposer can be customized for the heat load that the cooling interposer is to address. Each cooling interposer can include a connection or connections with the external plumbing 162. The external plumbing 162 can include separators 160 that can be employed to separate the fluid flow between inlet and outlet portions 164. The separators 160 can include any suitable material and be formed by, e.g., deposition or separately fabricated and installed.

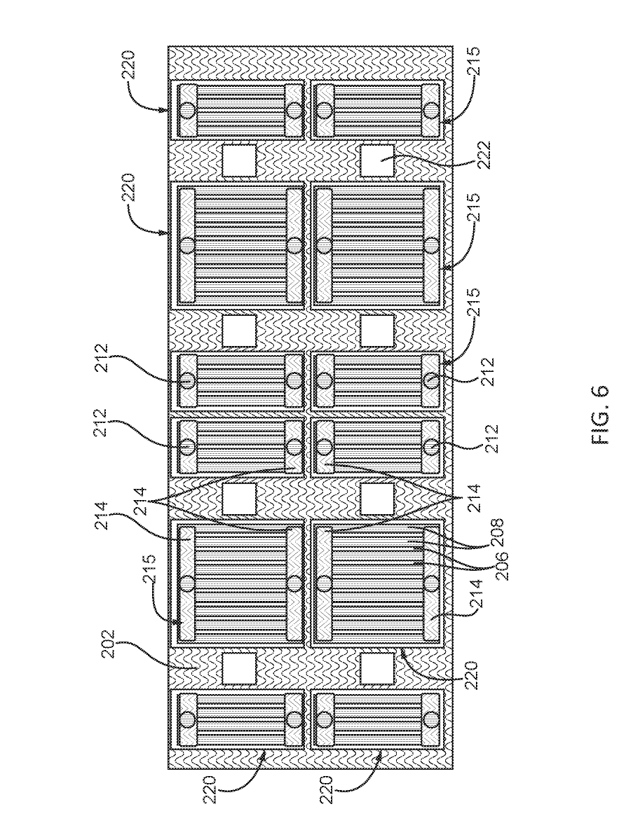

Referring to FIG. 6, a top view of a microchannel cooler layer for an interposer to be fabricated with microchannel coolers is shown in accordance with embodiments of the present invention. In an embodiment, a temporary carrier 202 can be employed to support the formation of the microchannel cooler layer with microchannel coolers 220. A number of different fabrication techniques can be employed to form the structure needed for the microchannel coolers 220.

The microchannel coolers 220 can be prefabricated by etching back material to expose metal lines or optical waveguides for mandrels 206 formed previously within device layers of an interposer structure. In other embodiments, structures of the microchannel coolers 220 or portions thereof can be applied to the temporary carrier 202 directly. Between the mandrels 206 of the microchannel coolers 220 is filled with temporary fill materials 208. The temporary fill materials 208 can include a water-absorbing polymer, such as, e.g., polyaspartic acid, a polyacrylate or other water absorbing polymer. The microchannel coolers 220 include a manifold structure for coolant inlets and outlets. An additional layer 215 can be added over end portions of mandrels 206 to create space for manifold structures 214 to connect later defined channels when the temporary fill materials 208 is removed. The additional layer 215 can be patterned using an etch mask and etch process.

In another embodiment, the mandrels 206 can be formed by providing electrical conduit or optical conduits at the locations needed for the microchannel coolers 220. In an example, the mandrels 206 can be formed as an array of through silicon waveguides (TSWs). The TSWs can include, e.g., Si/SiO₂ or Si₃N₄/SiO₂. In another example, the mandrels 206 can be formed as an array of through silicon vias (TSVs). The TSVs can include, e.g., copper vias with Ta/TaN or other barrier materials formed in lines. The mandrels 206 can be formed by other processes as well.

In another example, metal lines can be formed for the mandrels 206. In another example, the microchannel coolers 220 can be prefabricated and adhered to the temporary carrier 202. The mandrels 206 will remain to provide channels (microchannels) therebetween.

In an embodiment, spaces 222 for bridge chips can be provided between the microchannel coolers 220. Other components can also be provided at this stage of the fabrication. In an example, manifold structures 214 can be provided. The manifold structures 214 can include lines of material that are different than the temporary fill materials 208 to permit connections between channels (microchannels) when the temporary fill materials 208 is removed in later steps. The manifold structures 214 can include plugged openings 212, which are filled with temporary fill materials (plug) to be used later for fluid transfer. Openings can be formed through the additional layer 215 and plugged with temporary fill materials 208. The additional layer 215 can be removed after the temporary fill materials 208 is set.

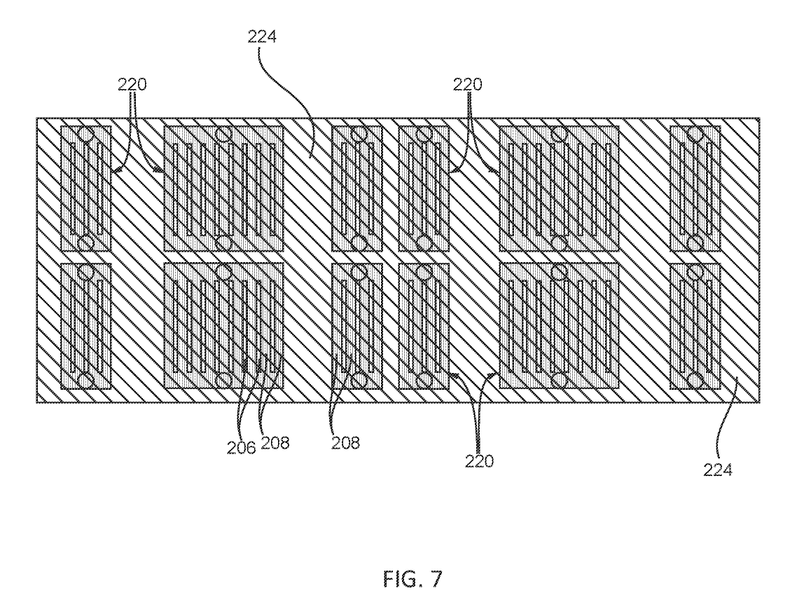

Referring to FIG. 7, a molding material 224 is applied over the temporary carrier 202 (FIG. 6). The microchannel coolers 220 are shown through the molding material 224. The molding material 224 can include, e.g., an epoxy.

Referring to FIG. 8, a grinding process can be performed to remove excess molding material 224 from a total planar surface. The molding material 224 forms side walls for the microchannel coolers 220. The mandrels 206 can be formed by structures, such as, e.g., TSW, TSV, etc.

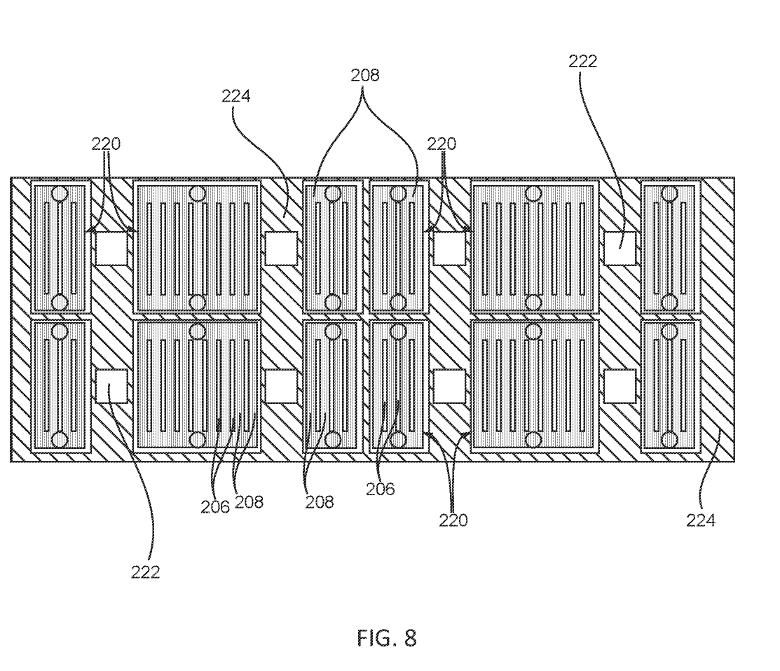

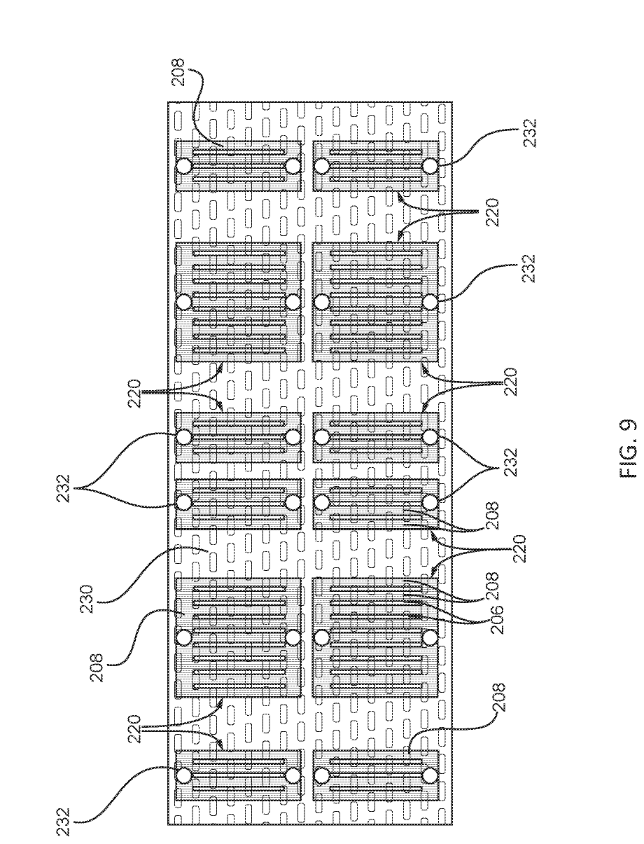

Referring to FIG. 9, redistribution layer (RDL) formation is performed. An RDL 230 can be fabricated over the molding material 224, the microchannel coolers 220 and other structures formed on the temporary carrier 202 (FIG. 6). The RDL 230 can include one or more layers of polymers for passivation and metal plating to form metal layers. The RDL 230 can also include semiconductor processing back-end-of-line (BEOL) structures. In this way, conductive paths are provided on and through an interposer being fabricated. It should be understood that conductive and/or optical paths can be carried through the microchannel coolers 220. This can include the use of vias or optical links for mandrels 206 or portions of mandrels 206 or by strategic placement of vias or optical links. The mandrels 206 are operationally active for conducting optical or electrical signals through the interposer to be formed.

Once the layers of the RDL 230 are completed, openings 232 are formed through the RDL 230 to expose the temporary fill materials 208 in the underlying layer (e.g., the microchannel cooler layer). The openings 232 provide access to the temporary fill materials 208 and will provide a fluid inlet/outlet for the microchannel coolers 220 during operation.

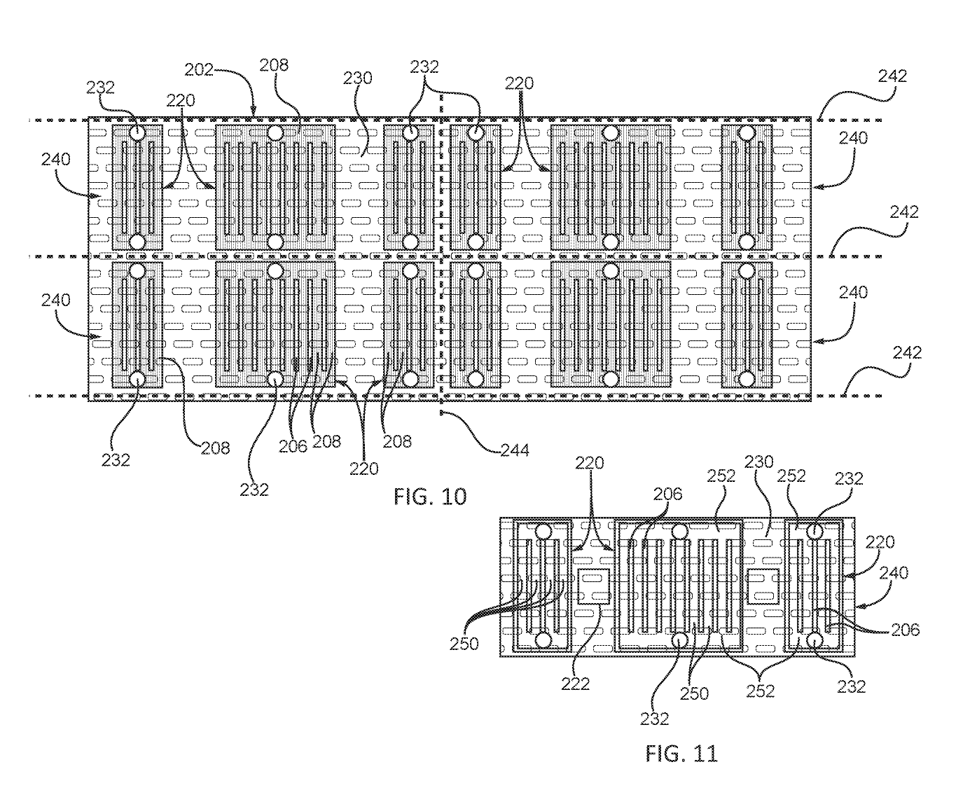

Referring to FIG. 10, the temporary carrier 202 is diced to form interposers 240. The dicing process cuts the temporary carrier 202 at dice lines 242 and 244 to define dimensions of interposers 240. The interposers 240 include the microchannel coolers 220 that are arranged for a particular package stack configuration. For example, interposer 240 includes spaces 222 for bridge chips and includes two microchannel coolers 220 corresponding to HBMs 112 and one microchannel cooler 220 corresponding to SOC 114 as depicted in the stack configuration of FIG. 2.

Referring to FIG. 11, the interposer 240 is subjected to an evaporation process to evaporate out the temporary fill materials 208, e.g., by subjecting the interposer 240 to a high temperature, e.g., greater than about 400 degrees C. Evaporation occurs through openings 232 and removes the temporary fill materials 208 from in between the mandrels 206 to form microchannels 250 and manifolds 252, for the formation of inlet and outlet passages that fluidly communicate with each of the microchannels 250 for a given microchannel cooler 220.

During operation, fluid can be circulated into and out of the microchannel coolers 220 by providing fluid into and out of openings 232 which in turn flows through manifolds 252 and the microchannels 250. In other embodiments, the mandrels 206 are conductive and do not have fluid channels. In this case, fluid can flow in manifolds 252 only (e.g., fluid flow at the ends but not along the mandrels 206) and heat is transferred by conduction through a grid of mandrels 206. It should be understood that the microchannels 250 and the microchannel coolers 220 can have any number of configurations and shapes. In an embodiment, mandrels and microchannels can have different sizes and shapes.

Referring to FIG. 12, an interposer 300 includes a microchannel cooler 302 having a radial burst pattern for mandrels 310 and microchannels 304. The radial burst pattern can provide a greater fluid flow (e.g., top left corner) from an inlet manifold 306 to outlet manifolds 308. The greater fluid flow can be placed at a hotspot or where greater heat transfer is needed. Other configurations can include higher density rectangular channels, channels with other shapes or features, etc.

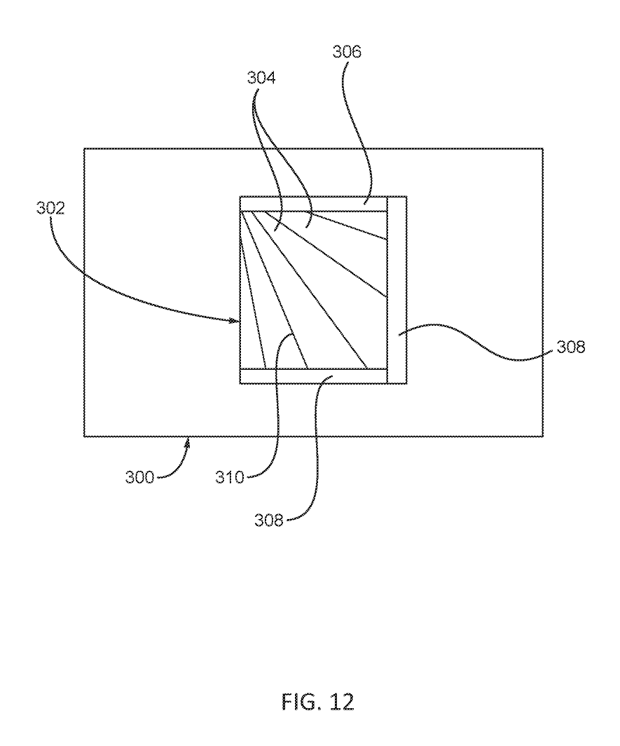

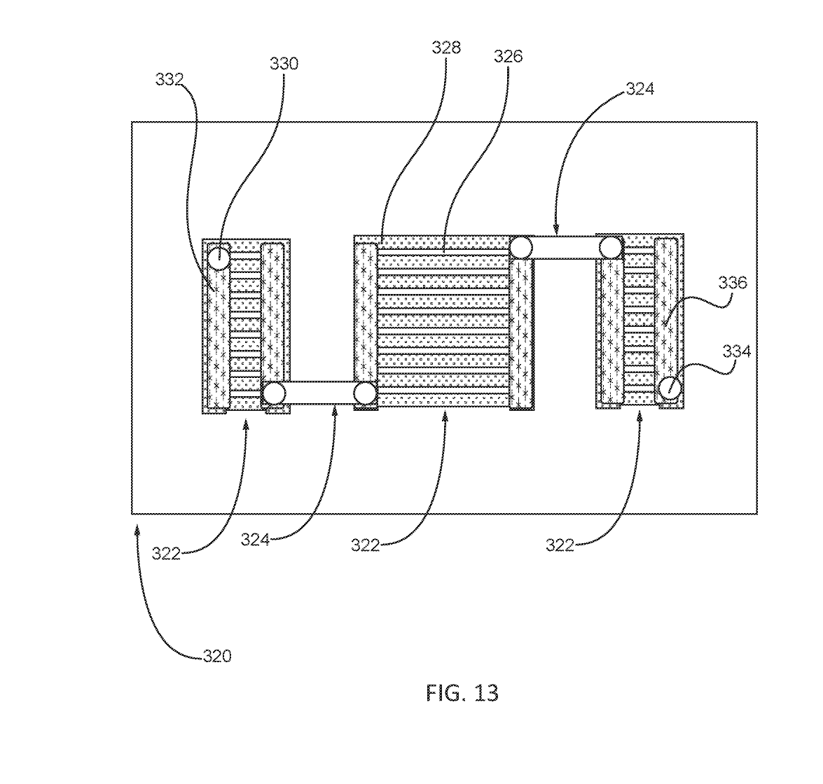

Referring to FIG. 13, an interposer 320 includes microchannel coolers 322 having mandrels 328 and microchannels 326. An inlet manifold 332 receives fluid from opening 330 and passes the fluid through the microchannels 326 and through connector channels 324 and finally out from an outlet manifold 336 and outlet 334. The connector channels 324 can be formed in the molding material during the formation process of the interposer 320. The connector channels 324 can be formed by depositing a temporary material and removing it later or by laser writing trenches to form the connector channels 324. Other methods are also contemplated.

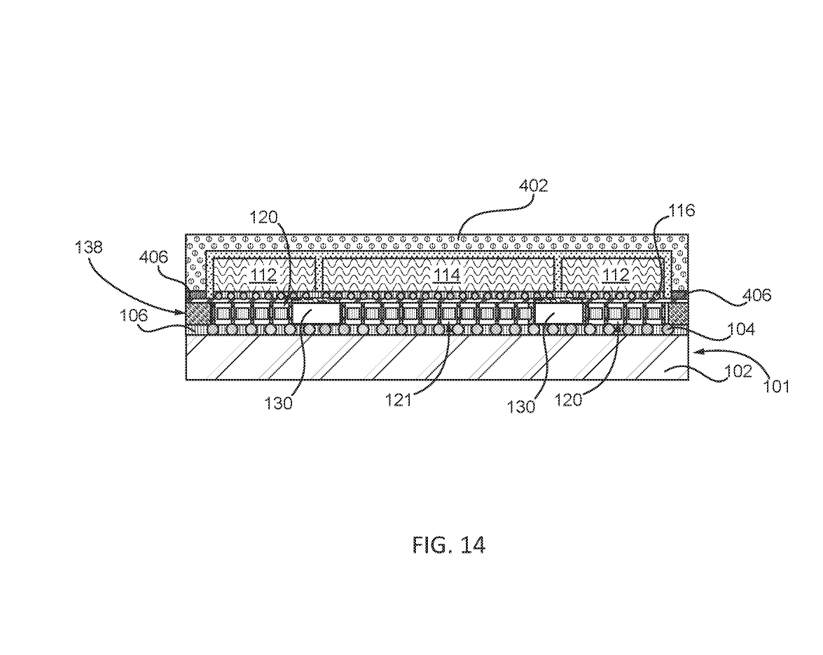

Referring to FIG. 14, a semiconductor package, such as semiconductor package 101 can be fitted with external plumbing to direct cooling fluid into and out of the interposer 138. The external plumbing can include a manifold 402 having inlet and outlet channels to provide an inlet fluid to the microchannel coolers 120, 121 formed in the interposer 138. In an embodiment, the manifold 402 can be fabricated separately and can be installed with communication between the microchannel coolers 120, 121. The manifold 402 can be connected using an adhesive 406. The manifold 402 can be routed favorably to optimize heat transfer. In an embodiment, the manifold 402 can be routed over the HBMs 112 and SOC 114 to further reduce heat loads in these components.

In other embodiments, the manifold 402 can be formed in place. This can include one or more depositions of material layers followed by etching to pattern in a shape of the manifold 402. Temporary material can be employed that is removed later by evaporative techniques or etching to form inlet and outlet channels through the manifold 402. Multiple manifolds are also contemplated and can be routed over different regions of the semiconductor package 101.

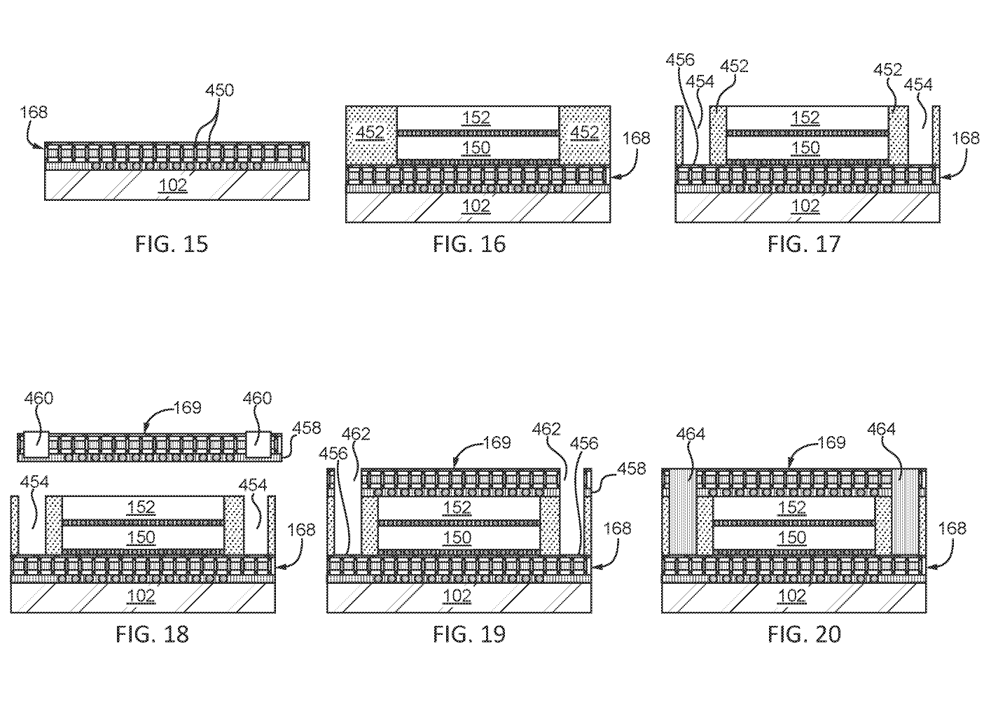

FIGS. 15-23 describe the fabrication of a semiconductor package 107 of FIG. 5 in greater detail.

Referring to FIG. 15, the interposer 168 having microchannel coolers 125 disposed thereon is connected to the substrate 102. The interposer 168 can include through vias 450 that can make electrical connections through the interposers 168 and can serve as sidewalls or mandrels to microchannels formed through the interposer 168.

Referring to FIG. 16, memory chip 150 is connected to the interposer 168 (soldered and underfilled) and the SOC 152 is connected to the memory chip 150 (soldered and underfilled). A molding process is performed to fill in gaps and to form a mold underfill 452. The mold underfill 452 can include, e.g., an epoxy.

Referring to FIG. 17, the mold underfill 452 is opened up, e.g., by a laser or by patterning using an etch process. Openings 454 are formed through the mold underfill 452 to expose the interposer 168. The interposer 168 includes inlet and outlet openings 456 within the openings 454, which can be connected to for fluid flow in later steps.

Referring to FIG. 18, a second interposer 169 is formed with a film-type underfill 458 or mold material thereon. The second interposer 169 also includes microchannel coolers 125. Inlet and outlet openings 460 are formed through the interposer 169. The interposer 169 is then connected to the SOC 152 (soldered and underfill).

Referring to FIG. 19, the film-type underfill 458 is removed, e.g., by laser. This opens up through mold vias 462 to again access inlet and outlet openings 456 in the interposer 168.

Referring to FIG. 20, a temporary fill 464 is employed to fill in the through mold vias 462. The temporary fill 464 will be removed in later steps to permit fluid flow through the interposers 168 and 169.

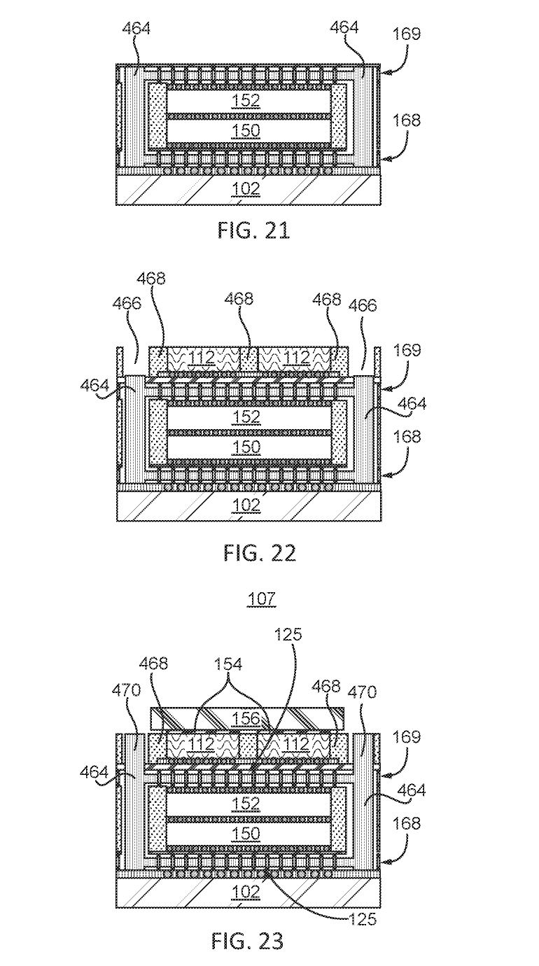

Referring to FIG. 21, the second interposer 169 is further processed to prepare for the installation for HBMs 112 in later steps.

Referring to FIG. 22, HBMs 112 are assembled on the second interposer 169. A mold material 468 is formed over the HBMs 112 and the second interposer 169. Openings 466 are formed in the mold material 468 to expose the temporary fill 464. The openings 466 can be formed using a laser to drill the openings 466. Then, the openings 466 are filled with a temporary fill 470 (FIG. 23).

Referring to FIG. 23, the heat spreader 156 (or heat sink) is applied to the HBMs 112 using a thermal interface material (TIM 154). When deployed the semiconductor package 107 can have the temporary fill 470 and 464 selectively removed to open up channels and microchannels in each of interposer 168 and second interposer 169 to open up fluid paths through the microchannel coolers 125.

The semiconductor package 107 can have manifolds and other plumbing structure connected to the semiconductor package 107. The plumbing structure can include pumps, flow meters, valves and other components to enable fluid flow through the semiconductor package 107.

The fluid employed for coolant can include a single-phase fluid (e.g., gas or liquid) or a two-phase fluid (e.g., gas and liquid). In some embodiments, the single-phase fluid and the two-phase fluid can include a fluorinated inert liquid, where different operating conditions are employed for single-phase fluid use and the two-phase fluid use. The fluorinated inert liquid is also a dielectric, which is particularly useful if the mandrels include conductive vias. In a single-phase microchannel cooler, sizes of microchannels can be uniform. Heights of vias (through mold vias) and/or heights of interconnects for fluid channels can be varied for expansion purposes in two-phase flows. Two-phase flow can be generated by controlling cooling structure sizes, shape height, length of channels and input / output manifolds, and/or electrical and optical interconnection structures that are made within, through or adjacent to microchannel coolers. Chips or chiplets can be angled (tilted) for expansion purposes in two-phase flow devices.

If the mandrels used to form the channels (microchannels) are electrical vias, then the fluid employed in the channels needs to be a dielectric material, e.g., a fluorinated inert liquid.

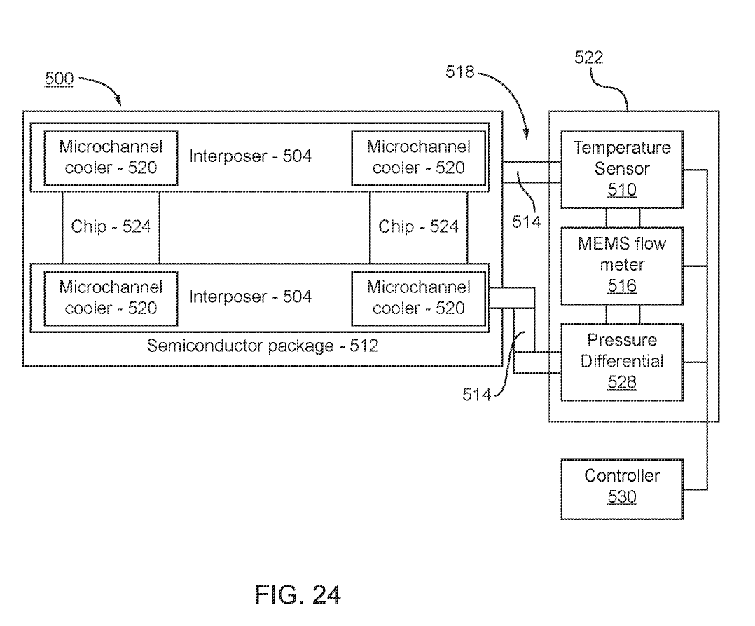

Referring to FIG. 24, a schematic diagram shows a system 500 for monitoring and controlling temperature in a semiconductor package. A fluid temperature of one or more interposers 504, each having one or more microchannel coolers 520, is measured and controlled using, e.g., a flow rate or other metric. The fluid temperature can be monitored using one or more temperature sensors 510 that monitor a target temperature of each chip 524 in a semiconductor package 512. The semiconductor package 512 can include one or more chips 524 that are adjacent to the interposers 504 that have one or more microchannel coolers 520 thereon.

The semiconductor package 512 can include multi-chip packages that can include optics devices, photonics devices, photonics integrated chips, electronic integrated chips or combinations of these or other devices. Manifolds or plumbing 514 can include a MEMS based flow meter 516 that can be employed in a feedback loop to control fluid flow in the microchannel coolers 520. Plumbing control loop(s) 518 can correspond to each interposer 504 or to each microchannel cooler 520. In other configurations, multiple interposers and/or multiple microchannel coolers 520 can employ a same plumbing control loop 518.

The plumbing control loops 518 can be disposed on the semiconductor package 512 or be external to the semiconductor package 512. If the plumbing control loops 518 are on the semiconductor package 512 they can include or be connected to one or more heat sinks 522. A controller 530 can be employed to control the flow rate of the MEMS flow meter 516 in accordance with the temperature measured by the temperature sensors 510. The controller 530 can increase or decrease the flow using a pressure differential device 528, e.g., a pump. In an embodiment, the controller 530 can be implemented by one or more of the chips 524.

Exemplary applications/uses to which the present invention can be applied include but are not limited to semiconductor devices. Semiconductor devices can include processors, memory devices, application specific integrated circuits (ASICs), logic circuits or devices, combinations of these and any other circuit device. In such devices, one or more semiconductor devices can be included in a central processing unit, a graphics processing unit, and/or a separate processor- or computing element-based controller (e.g., logic gates, etc.). The semiconductor devices can include one or more on-board memories (e.g., caches, dedicated memory arrays, read only memory, etc.). In some embodiments, the semiconductor devices can include one or more memories that can be on or off board or that can be dedicated for use by a hardware processor subsystem (e.g., ROM, RAM, basic input/output system (BIOS), etc.).

In some embodiments, the semiconductor devices can include and execute one or more software elements. The one or more software elements can include an operating system and/or one or more applications and/or specific code to achieve a specified result. In still other embodiments, the semiconductor devices can include dedicated, specialized circuitry that perform one or more electronic processing functions to achieve a specified result. Such circuitry can include one or more field programmable gate arrays (FPGAs), and/or programmable applications programmable logic arrays (PLAs).

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher-level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” “top,” “bottom,” “backside,” “frontside” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of devices and methods (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. An interposer, comprising:
a microchannel cooler layer including a microchannel cooler, the microchannel cooler having a plurality of mandrels connected between an inlet and an outlet, the plurality of mandrels being thermally conductive to permit heat transfer from the plurality of mandrels to the inlet and the outlet; and
a redistribution layer on the microchannel cooler layer and having openings fluidly connected to the inlet and the outlet to permit fluid flow between the inlet and the outlet.

2. The interposer of claim 1, wherein the plurality of mandrels form channels to permit fluid flow between the inlet and the outlet.

3. The interposer of claim 1, wherein the plurality of mandrels include electrical vias and/or optical waveguides.

4. The interposer of claim 1, wherein the plurality of mandrels are configured in a radial burst pattern.

5. The interposer of claim 1, wherein the microchannel cooler is positioned to address a specific heat load.

6. The interposer of claim 1, further comprising a semiconductor chip disposed within the microchannel cooler layer.

7. The interposer of claim 1, wherein the microchannel cooler layer includes:
at least one other microchannel cooler; and
a semiconductor chip disposed between the microchannel cooler and the at least one other microchannel cooler.

8. A device, comprising:
a substrate;
an interposer connected to the substrate, the interposer including at least one microchannel cooler; and
at least one semiconductor chip connected to the interposer, wherein the at least one microchannel cooler is configured to provide active cooling to the at least one semiconductor chip.

9. The device of claim 8, wherein the at least one microchannel cooler includes a plurality of microchannels configured for fluid flow.

10. The device of claim 9, wherein the plurality of microchannels are formed between mandrels within the interposer.

11. The device of claim 10, wherein the mandrels include electrical vias and/or optical waveguides.

12. The device of claim 8, further comprising a manifold structure fluidly connected to the at least one microchannel cooler.

13. The device of claim 12, wherein the manifold structure is external to the interposer.

14. The device of claim 8, further comprising a plumbing control loop having a micro-electro-mechanical system flow meter to control a fluid flow through the at least one microchannel cooler.

15. The device of claim 8, further comprising another chip disposed within the interposer between adjacent microchannel coolers.

16. A device, comprising:
a substrate;
a first interposer connected to the substrate, the first interposer having a first microchannel cooler;
at least one semiconductor chip connected to the first interposer;
a second interposer including a second microchannel cooler; and
an external plumbing structure fluidly connected to the first microchannel cooler of the first interposer and the second microchannel cooler of the second interposer.

17. The device of claim 16, wherein the first microchannel cooler of the first interposer and the second microchannel cooler of the second interposer are configured to provide active cooling to the at least one semiconductor chip wherein the external plumbing structure includes fluid inlet and outlet connections to provide coolant flow through microchannel coolers.

18. The device of claim 16, wherein the first microchannel cooler of the first interposer and the second microchannel cooler of the second interposer include a plurality of microchannels formed between mandrels, wherein the mandrels include electrical vias that provide electrical connections and optical waveguides that provide optical connections.

19. The device of claim 16, further comprising a second semiconductor chip connected to the second interposer.

20. The device of claim 16, wherein the external plumbing structure includes a manifold having inlet and outlet portions fluidly connected with the first microchannel cooler of the first interposer and the second microchannel cooler of the second interposer.
